(19) United States
(12) Patent Application Publication
(10) Pub. No.: US 2025/0204214 A1
(43) Pub. Date: Jun. 19, 2025

(54) DISPLAY DEVICE AND METHOD FOR MANUFACTURING SAME

(71) Applicant: Sharp Display Technology Corporation, Kameyama City, Mie (JP)

(72) Inventor: Takayuki YAMADA, Kameyama City, Mie (JP)

(21) Appl. No.: 18/852,433

(22) PCT Filed: May 18, 2022
(86) PCT No.: PCT/JP2022/020694

§ 371 Date: Sep. 27, 2024

(51) Int. Cl. H10K 59/80; H10K 59/40; H10K 77/10; H10K 102/00

(52) U.S. Cl. CPC H10K 59/8722; H10K 59/40; H10K 59/8793; H10K 77/111; H10K 2102/311

(57) ABSTRACT

An organic EL display device includes a polarizing plate stacked on a display panel. The display panel has a picture-frame region provided around the display region. A folding portion provided in the picture-frame region is folded about a folding axis extending in a first direction. The picture-frame region is provided with a touch panel line extending to cross the folding portion in a second direction perpendicular to the first direction. The polarizing plate is attached through a first adhesive layer to the display region. The folding portion is provided not with the polarizing plate but with the first adhesive layer to cover the touch panel line.

### TECHNICAL FIELD

The present disclosure relates to a display device and a method for manufacturing the display device.

### BACKGROUND ART

In recent years, organic electroluminescence (EL) display devices using organic EL elements have been put into practical use to serve as light-emitting elements. These organic EL display devices include flexible organic EL display devices. A proposed flexible organic EL display device has organic EL elements provided on a flexible resin substrate.

The organic EL display device is provided with: a display region that displays an image; and a picture-frame region positioned around the display region. The picture-frame region has an end portion provided with a terminal unit. Demands on the organic EL display device include a reduction of the picture-frame region in size. In order to meet such a demand, in the flexible organic EL display device, the picture-frame region toward the terminal unit is folded.

An organic EL display device with the picture-frame region folded is disclosed in, for example, Patent Document 1. In the organic EL display device disclosed in Patent Document 1, the picture-frame region has a folding region; that is, a folding portion, and the folding region is provided with a protective member made of resin. The folding portion has a signal wire extending across the folding portion. The protective member covers and protects members such as the signal wire.

### CITATION LIST

### Patent Literature

[Patent Document 1] Japanese Unexamined Patent Application Publication No. 2019-159280

### SUMMARY

### Technical Problems

In the organic EL display device of Patent Document 1, if the protective member has a portion over a polarizing plate, the portion over the protective member is likely to bear air bubbles. Such air bubbles might form an entry path for moisture and oxygen. Whereas, if the protective member does not reach an end face of the polarizing plate, a gap opening between the polarizing plate and the protective member might form the entry path for moisture and oxygen. In this case, the protective member cannot play a role of protecting, for example, the signal wire from moisture and oxygen.

The present disclosure sets out to appropriately protect a wire extending in a folding portion included in a picture-frame region of a display device.

### Solution to Problems

A technique of the present disclosure relates to a display device. The display device according to a technique of the present disclosure includes: a display panel; and a plate body stacked on the display panel. The display panel has: a display region that displays an image; and a picture-frame region provided around the display region. The picture-frame region includes: a terminal unit provided with a plurality of terminals; and a folding portion provided between the terminal unit and the display region.

The folding portion is folded about a folding axis extending in a first direction. The picture-frame region is provided with a wire extending to cross the folding portion in a second direction perpendicular to the first direction. The plate body is attached through a first adhesive to a portion, of the display panel, including the display region.

Furthermore, the folding portion is provided not with the plate body but with the first adhesive to cover the wire. Alternatively, the plate body has a flexible portion in which a portion around the folding axis is more flexible than an other portion. The folding portion is provided with the first adhesive together with the flexible portion, so as to cover the wire.

### Advantageous Effect of Disclosure

A technique of the present disclosure can appropriately protect a wire extending in a folding portion included in a picture-frame region of a display device.

### BRIEF DESCRIPTION OF DRAWINGS

FIG. 1 is a plan view illustrating an example of a schematic configuration of an organic EL display device according to an embodiment.

FIG. 2 is a cross-sectional view of the organic EL display device, taken along line II-II in FIG. 1.

FIG. 3 is a plan view illustrating an example of a schematic configuration of a display panel.

FIG. 4 is a plan view illustrating an example of a schematic configuration of a touch panel.

FIG. 5 is a plan view illustrating an example of pixels and various display wires included in a display region surrounded by V in FIG. 3.

FIG. 6 is a cross-sectional view of the organic EL display device, taken along line VI-VI in FIG. 5.

FIG. 7 is an equivalent circuit diagram illustrating an example of a pixel circuit.

FIG. 8 is a cross-sectional view illustrating an example of a schematic configuration of a folding portion in the organic EL display device of the embodiment.

FIG. 9 is a cross-sectional view illustrating an example of a schematic configuration of the folding portion in the organic EL display device of a first modification.

FIG. 10 is a cross-sectional view illustrating an example of a schematic configuration of the folding portion in the organic EL display device of a second modification.

### DESCRIPTION OF EMBODIMENTS

Exemplary embodiments will be described in detail below with reference to the drawings. In the embodiments below, an organic EL display device is described as an example of a display device according to a technique of the present disclosure. Note that the drawings conceptually illustrate the technique of the present disclosure. Hence, the drawings may either exaggerate or simplify the dimensions, ratios or numbers to facilitate understanding of the techniques of the present disclosure.

The embodiments below include a statement describing that, above a constituent feature such as a film, layer, or element, an other constituent feature such as an other film, layer or element is provided or formed. The statement means not only a case where the other constituent feature is found immediately above the constituent feature, but also a case where still an other constituent feature such as still an other film, layer, or element is provided between the constituent feature and the other constituent feature.

Moreover, the embodiments below includes a statement describing that a constituent feature such as a film, layer, or element is connected to an other constituent feature such as an other film, layer, or element. Such a statement means that the constituent features are electrically connected together unless otherwise specified. The statement means not only a case of direct connection but also a case of indirect connection through still an other constituent feature such as still an other film, layer, or element, unless otherwise departing from the scope of the present disclosure.

In addition, the embodiments below include a statement describing that a constituent feature such as a film, layer, or element is included in the same layer as a layer of an other constituent feature such as an other film, layer, or element. Such a statement means that both of the constituent features are formed in the same process. A statement describes that a constituent feature is provided below an other constituent feature. Such a statement means that the constituent feature is formed in a process preceding the process of the other constituent feature. A statement describes that a constituent feature is provided above an other constituent feature. Such a statement means that the constituent feature is formed in a process succeeding the process of the other constituent feature.

Moreover, the embodiments below include a statement describing that a constituent feature such as a film, layer, or element is the same as, or identical to, an other constituent feature such as an other film, layer, or element. Such a statement means not only a case where the constituent feature is completely the same as, or completely identical to, the other constituent feature, but also a case where the constituent feature is substantially the same as, or substantially identical to, the other constituent feature within production variation and tolerance.

### Embodiment

An organic EL display device 1 of this embodiment is used for various appliances such as mobile devices including multi-function cellular phones referred to as smart phones and tablet terminals, personal computers (PCs), and television devices. The organic EL display device 1 of this example is a display device provided with a touch panel that allows a user to carry out an input operation with a touch of the screen.

### Configuration of Organic EL Display Device

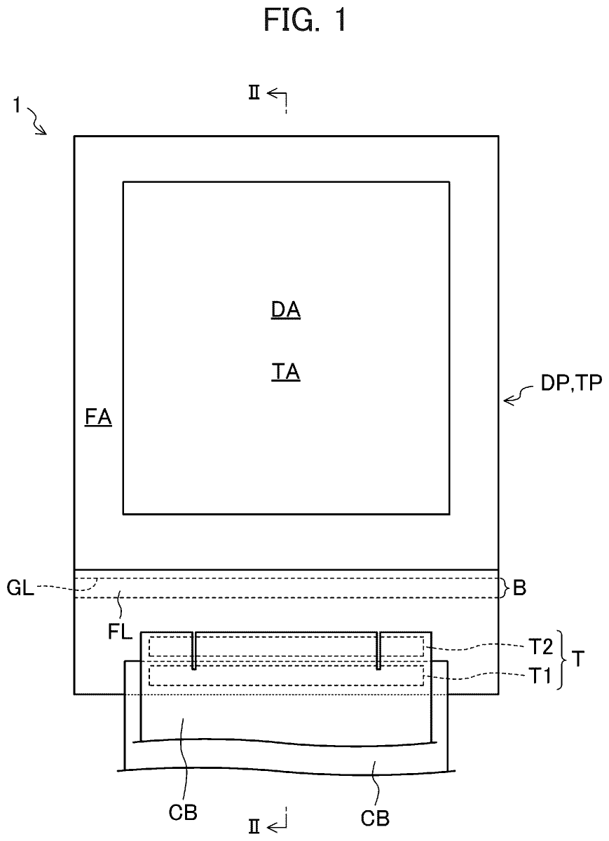

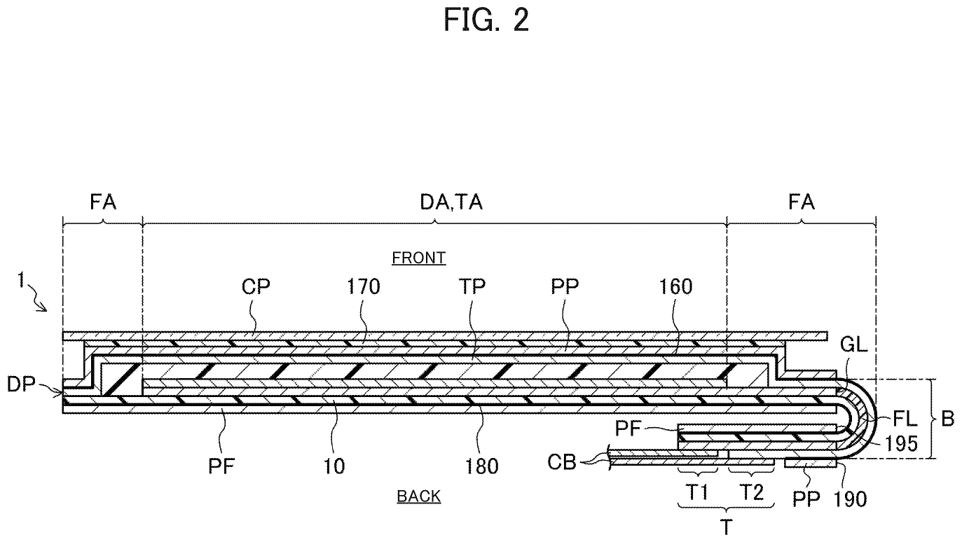

The organic EL display device 1 has functions of displaying an image and simultaneously detecting a touch position on a screen that displays an image. As illustrated in FIGS. 1 and 2, the organic EL display device 1 includes: a display panel DP; a touch panel TP; a back face protective film PF; a polarizing plate PP; and a cover panel CP. The display panel DP and the touch panel TP constitute a panel body PL. The polarizing plate PP and the cover panel CP are stacked on top of each other in the stated order above the panel body PL.

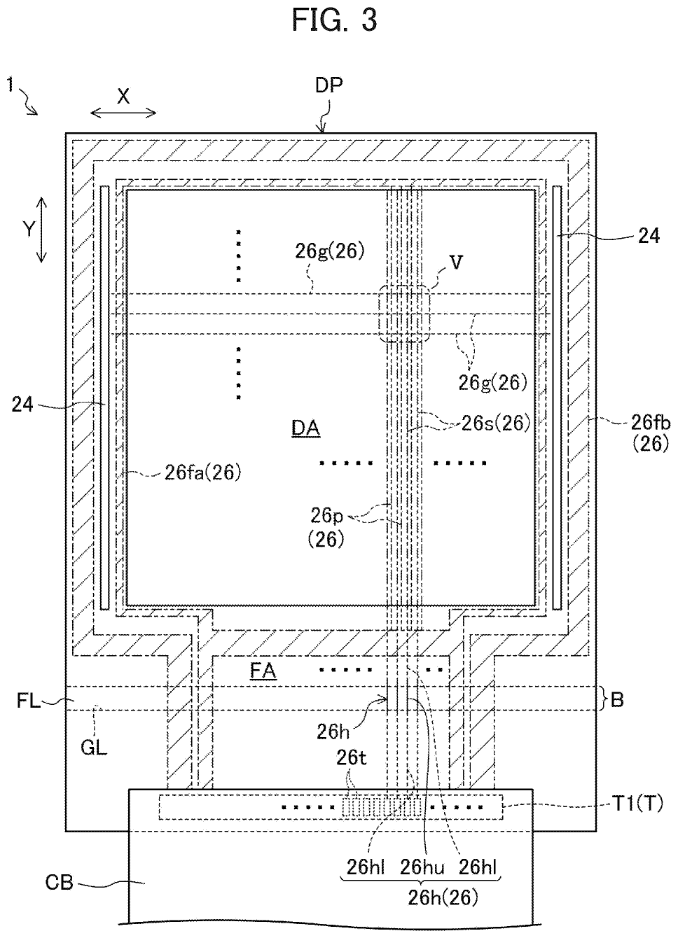

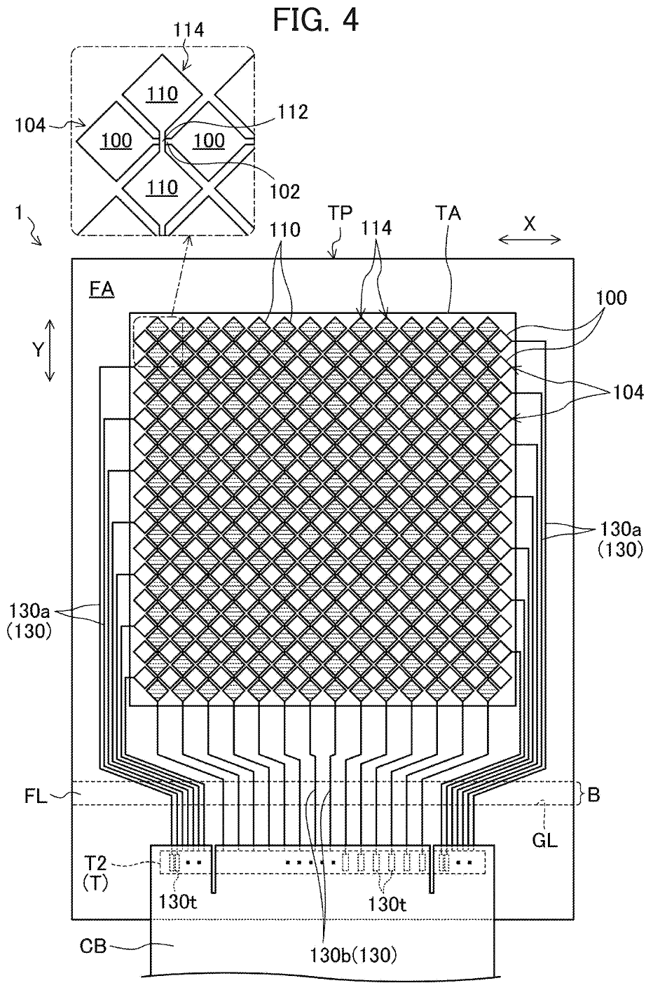

The organic EL display device 1 is provided with: a display region DA; a touch region TA; and a picture-frame region FA. The display panel DP has: the display region DA; and the picture-frame region FA (see FIG. 3). The touch panel TP has: the touch region TA; and the picture-frame region FA (see FIG. 4). The display region DA and the touch region TA are set in the same position to overlap with each other in the same size. The picture-frame region FA is provided around the display region DA and the touch region TA.

The display region DA is a region that displays an image. The display region DA is a screen. The display region DA is shaped into, for example, a rectangle. The display region DA may be shaped into a substantial rectangle such as a rectangle having at least one of the sides as an arc-like side, a rectangle having at least one of the corners as a rounded corner, or a rectangle having at least one of the sides as a partially notched side. The display region DA may also be shaped into any given shape.

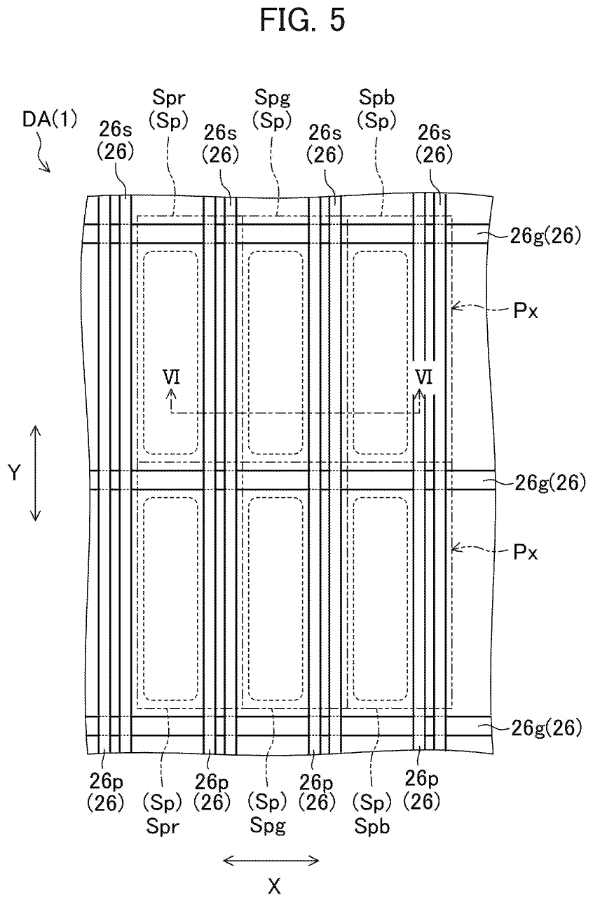

As illustrated in FIG. 5, the display region DA includes a plurality of pixels Px. The plurality of pixels Px are arranged in a matrix. Each of the pixels Px includes three subpixels Sp. The three subpixels Sp include a subpixel Spr that emits a red light, a subpixel Spg that emits a green light, and a subpixel Spb that emits a blue light. These three subpixels Spr, Spg, and Spb are arranged, for example, in stripes.

The touch region TA illustrated in FIGS. 1 and 2 is a region for detecting a touch position touched with a contact object. The contact object includes a finger of a user and a stylus. The touch region TA is shaped into, for example, a rectangle. A shape of the touch region TA corresponds to a shape of the display region DA. That is, the touch region TA may be substantially rectangular as described above. Alternatively, the touch region TA may have any given shape.

The picture-frame region FA is provided out of the screen, and presents no image. The picture-frame region FA is shaped into, for example, a rectangular frame. The picture-frame region FA may be shaped into a frame other than a rectangular frame. The picture-frame region FA includes: a terminal unit T; and a folding portion B. The terminal unit T is a portion for connecting with an external circuit. The terminal unit T includes: a first terminal unit T1; and a second terminal unit T2.

The first terminal unit T1 and the second terminal unit T2 are provided to a portion forming one side of the picture-frame region FA. The first terminal unit T1 is positioned near an outer edge of the picture-frame region FA. The first terminal unit T1 supplies a signal to the display panel DR The second terminal unit T2 is positioned closer to the display region DA than the first terminal unit T1. The second terminal unit T2 applies a voltage to the touch panel DP.

The folding portion B is provided between the terminal unit T (strictly, the second terminal unit T2) in the picture-frame region FA and the display region DA. The folding portion B is a portion to be folded about a folding axis Ab extending in a first direction X; that is, in a horizontal direction in FIG. 1. The folding portion B extends transversely across the picture-frame region FA in the first direction X.

The picture-frame region FA of the organic EL display device 1 is folded at the folding portion B at an angle of, for example, 180° in a U-shape. Thus, both the first terminal unit T1 and the second terminal unit T2 are laid in back of the organic EL display device 1. To each of the first terminal unit T1 and the second terminal unit T2, a wiring board CB such as a flexible printed circuit (FPC) is connected.

### Display Panel

The display panel DP is an active-matrix display panel. In the active-matrix display panel DP, a thin-film transistor (hereinafter referred to as a TFT) 30 controls light to be emitted from each of the subpixels Sp. The TFT 30 operates to display an image.

As illustrated in FIG. 2, the display panel DP includes: a substrate layer 10; a TFT layer 20; a light-emitting element layer 60; and a sealing film 80.

### Substrate Layer

The substrate layer 10 is a base layer of the display panel PD. The substrate layer 10 is flexible. The substrate layer 10 is formed of an organic resin material such as polyimide resin, polyamide, or epoxy resin. The substrate layer 10 may be formed of a multilayer film in which an inorganic insulating film and a resin layer are stacked on top of each other. The inorganic insulating film may be made of silicon oxide, and the resin layer may be made of the organic resin material described above.

### TFT Layer

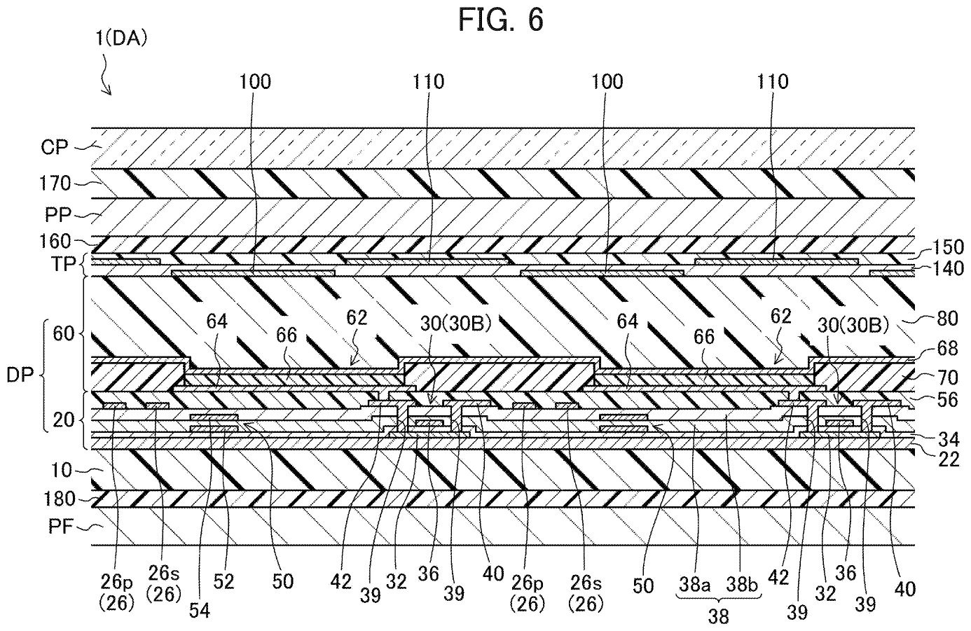

As illustrated in FIGS. 3, 5 and 6, the TFT layer 20 includes: a base coat film 22; a drive circuit 24; various wires 26; a plurality of the TFTs 30; a plurality of capacitors 50; and a planarization film 56. The drive circuit 24, the various wires 26, the plurality of TFTs 30, and the plurality of capacitors 50 are provided above the base coat film 22. The base coat film 22 is provided over a substantially entire surface of the substrate layer 10.

The drive circuit 24 is provided to the picture-frame region FA. In the picture-frame region FA, the drive circuit 24 is disposed to each of the sides (the left side and the right side in FIG. 1) adjacent to the side provided with the first terminal unit T1 and the second terminal unit T2. The drive circuit 24 includes a gate driver. The drive circuit 24 is monolithically formed in the display panel DP.

The various wires 26 include: a first picture-frame line 26fa; a second picture-frame 26fb; a plurality of lead lines 26h; a plurality of gate lines 26g; a plurality of source lines 26s; and a plurality of power supply lines 26p.

The first picture-frame line 26fa is provided to the picture-frame region FA. The first picture-frame line 26fa is shaped into a picture frame, and provided closer to the display region DA than the drive circuit 24. The first picture-frame line 26fa has a portion provided toward the terminal unit T and extending to the first terminal unit T1. The first picture-frame line 26fa is supplied with a high-level power supply voltage (ELVDD) through the wiring board CB.

The second picture-frame line 26fb is provided to the picture-frame region FA. The second picture-frame line 26fb is shaped into a substantial C-shape, and provided to run an outer side of the drive circuit 24. Opposing end portions of the second picture-frame line 26fb extend toward the first terminal unit T1 along the first picture-frame line 26fa. The second picture-frame line 26fb is supplied with a low-level power supply voltage (ELVSS) through the wiring board CB.

The plurality of lead lines 26h are provided to the picture-frame region FA. Each of the lead lines 26h is lead out from the display region DA in the display panel DP, and extends to the first terminal unit T1. The lead lines 26h have respective end portions positioned in the first terminal unit T1 and serving as terminals 26t. The first terminal unit T1 is provided with the plurality of terminals 26t. Each of the lead lines 26h includes: a lower lead line 26hl; and an upper lead line 26hu.

In the picture-frame region FA, a plurality of the lower lead lines 26hl have portions provided between the display region DA and the folding portion B, and other portions provided between the folding portion B and the first terminal unit T1. These portions are spaced apart from one another in the first direction X, and extend in parallel with one another in the second direction Y Each of the lower lead lines 26hl, positioned closer to the display region DA than the folding portion B, is connected to a corresponding one of the source lines 26s through a contact hole formed in the interlayer insulating film 38.

In the picture-frame region FA, the plurality of upper lead lines 26hu are spaced apart from one another in the first direction X, provided to cross the folding portion B, and laid in parallel with one another in the second direction Y Each of the upper lead lines 26hu is connected through a contact hole 38h formed in the interlayer insulating film 38 to a corresponding lower lead line 26hl positioned closer to the display region DA than the folding portion B, and to a corresponding lower lead line 26hl positioned closer to the first terminal unit T1 than the folding portion B.

To each of the terminals 26t of the first terminal unit T1, a source driver (not shown) is connected through the wiring board CB. Each terminal 26t and the wiring board CB are connected together, using an anisotropic conductive junction material such as an anisotropic conductive film (ACF). The source driver is a circuit to supply a signal to a wire (e.g., a source line 26s) and the drive circuit 24 included in the display panel DP, in order to control image display.

Each of the plurality of gate lines 26g is a wire to transmit a gate signal. In the display region DA, the plurality of gate lines 26g are spaced apart from one another in the second direction Y, and extend in parallel with one another in the first direction X. The gate lines 26g are provided for the respective rows of the subpixels Sp. Each of the gate lines 26g is connected to a gate driver of the drive circuit 24.

Each of the plurality of source lines 26s is a wire to transmit a source signal. In the display region DA, the plurality of source lines 26s are spaced apart from one another in the first direction X, and extend in parallel with one another in the second direction Y The source lines 26s are provided for the respective columns of the subpixels Sp. Each of the source lines 26s is lead out to the first terminal unit T1, and serves as a lead line 26h.

Each of the plurality of power supply lines 26p is a wire to apply a predetermined high-level power supply voltage (ELVDD). In the display region DA, the plurality of power supply lines 26p are spaced apart from one another in the first direction X, and extend in parallel with one another in the second direction Y The power supply lines 26p are provided for the respective columns of the subpixels Sp. Each of the power supply lines 26p is connected to the first picture-frame line 26fa.

Any of the plurality of TFTs 30 are top gate TFTs. Two or more of the TFTs 30 are provided for each of the subpixels Sp. The TFTs 30 are an example of active elements. Each of the plurality of TFTs 30 includes: a semiconductor layer 32; a gate insulating film 34; a gate electrode 36; an interlayer insulating film 38; a first terminal electrode 40; and a second terminal electrode 42.

The semiconductor layer 32 is shaped into islands and provided on the base coat film 22. The semiconductor layer 32 is individually separated from one another for the respective TFTs 30. The semiconductor layer 32 may be provided monolithically. The semiconductor layer 32 is formed of, for example, low-temperature polysilicon (LTPS). The semiconductor layer 32 may be formed of an oxide semiconductor such as indium gallium zinc oxide (In—Ga—Zn—O).

The gate insulating film 34 covers a plurality of the semiconductor layers 32. The gate insulating film 34 is provided monolithically on the base coat film 22. The gate insulating film 34 may be shaped into islands provided on the respective semiconductor layers 32, and individually separated from one another for the respective TFTs 30. The gate electrode 36 is provided on the gate insulating film 34. The gate electrode 36 overlaps with the semiconductor layers 32 through the gate insulating film 34.

The interlayer insulating film 38 includes: a first interlayer insulating film 38a; and a second interlayer insulating film 38b. The first interlayer insulating film 38a and the second interlayer insulating film 38b are provided in the stated order above the gate insulating film 34. The interlayer insulating film 38 covers a plurality of the gate electrodes 36. The gate insulating film 34 and the interlayer insulating film 38 have contact holes 39. A pair of contact holes 39 is provided for each of the TFTs 30.

The contact holes 39 in a pair penetrate through opposing portions (conduction regions), of the semiconductor layer 32, across a region (an intrinsic region) overlapping with the gate electrode 36. The first terminal electrode 40 and the second terminal electrode 42 are provided on the interlayer insulating film 38. The first terminal electrode 40 and the second terminal electrode 42 are spaced apart from each other, and connected to the conduction regions of the semiconductor layer 32 through the respective contact holes 39.

At least one of the plurality of capacitors 50 is provided for each of the subpixels Sp. Each of the capacitors 50 includes: a first capacitive electrode 52; and a second capacitive electrode 54. The first capacitive electrode 52 is provided on the gate insulating film 34. The second capacitive electrode 54 is provided on the first interlayer insulating film 38a. The first capacitive electrode 52 and the second capacitive electrode 54 overlap with each other through the first interlayer insulating film 38a.

The base coat film 22, the gate insulating film 34, the first interlayer insulating film 38a, and the second interlayer insulating film 38b are made of an inorganic insulating material such as, for example, silicon oxide, silicon nitride, or silicon oxynitride. The base coat film 22, the gate insulating film 34, the first interlayer insulating film 38a, and the second interlayer insulating film 38b are either monolayer films or multilayer films made of such inorganic insulating materials.

The gate line 26g, the lower lead line 26hl, the gate electrode 36, and the first capacitive electrode 52 are formed of the same material and in the same layer. The first picture-frame line 26fa, the second picture-frame line 26fb, the upper lead line 26hu, the source line 26s, the power supply line 26p, the first terminal electrode 40, and the second terminal electrode 42 are formed of the same material and in the same layer.

The above various wires and electrodes including the second capacitive electrode 54 are made of such metal materials as, for example, aluminum (Al), tungsten (W), molybdenum (Mo), tantalum (Ta), chromium (Cr), titanium (Ti), and copper (Cu). These various wires and electrodes are monolayer films or multilayer films made of such metal materials.

The planarization film 56 is provided to cover, in the display region DA, the source line 26s, the power supply line 26p, the first terminal electrode 40, and the second terminal electrode 42. The planarization film 56 is made of, for example, such an organic resin material as polyimide resin or acrylic resin. Alternatively, the planarization film 56 is made of a polysiloxane-based spin-on-glass (SOG) material. The TFT layer 20 has a surface planarized with the planarization film 56.

### Light-Emitting Element Layer

The light-emitting element layer 60 is provided on the TFT layer 20. The light-emitting element layer 60 includes a plurality of organic electroluminescence (EL) elements 62. The organic EL elements 62 are an example of light-emitting elements. The organic EL elements 62 are top-emission organic EL elements. The top-emission organic EL elements 62 release light, emitted by an organic EL layer 66, from toward the cover panel CP. Each of the organic EL elements 62 includes: a pixel electrode 64; the organic EL layer 66; and a common electrode 68.

The pixel electrode 64 is provided for each of the subpixels Sp. A plurality of the pixel electrodes 64 are arranged in a matrix in association with the subpixels Sp. The pixel electrodes 64 are provided on the planarization film 56. Each of the pixel electrodes 64 is reflective to light. The pixel electrode 64 functions as an anode. The pixel electrode 64 is preferably formed of a material having a large work function.

The pixel electrodes 64 are partitioned with an edge cover 70. The edge cover 70 is provided on the planarization film 56. The edge cover 70 is formed in a grid pattern, and covers a peripheral edge portion of each of the pixel electrodes 64. The edge cover 70 is made of, for example, such an organic resin material as polyimide resin or acrylic resin. Alternatively, the edge cover 70 is made of a polysiloxane-based spin-on-glass (SOG) material.

The organic EL layer 66 is provided on an individual pixel electrode 64 in an opening of the edge cover 70. The organic EL layer 66 has: a hole injection layer; a hole transport layer; a light-emitting layer; an electron transport layer; and an electron injection layer, all of which are provided in the stated order above the pixel electrode 64. The hole injection layer, the hole transport layer, the light-emitting layer, the electron transport layer, and the electron injection layer are made of known compounds suitable for the functions of the respective layers.

The common electrode 68 is monolithically provided in common to the plurality of subpixels Sp. The common electrode 68 is provided on a plurality of the organic EL layers 66, and covers the edge cover 70. The common electrode 68 overlaps with the pixel electrodes 64 through the organic EL layers 66. The common electrode 68 is transparent to light. The common electrode 68 functions as a cathode. The common electrode 68 is preferably formed of a material having a small work function. The common electrode 68 extends to the picture-frame region FA, and connects to the second picture-frame line 26fb.

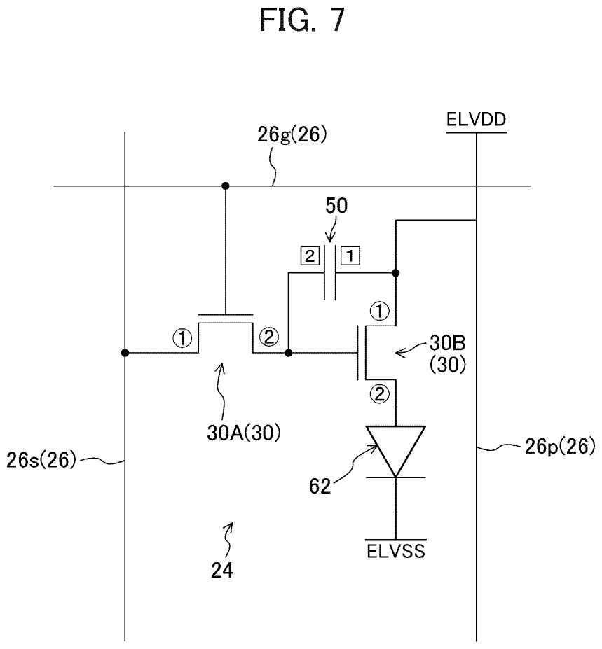

A plurality of TFTs 30, a capacitor 50, and an organic EL element 62 are provided for each of the subpixels Sp, and constitute a pixel circuit Pc as illustrated in FIG. 7. The pixel circuit Pc controls light to be emitted from the organic EL element 62 provided to the corresponding subpixel Sp, in accordance with: a gate signal to be supplied to the gate line 26g; a source signal to be supplied to the source line 26s; a high-level power supply voltage to be supplied to the power supply line 26p; and a low-level power supply voltage to be supplied to the common electrode 68.

In the equivalent circuit diagram in FIG. 7, each of the TFTs 30 has: a first terminal electrode 40 denoted by a circled numeral 1; and a second terminal electrode 42 denoted by a circled numeral 2. Furthermore, the capacitor 50 has: a first capacitive electrode 52 denoted by a squared numeral 1; and a second capacitive electrode 54 denoted by a squared numeral 2. The plurality of TFTs 30 constituting the pixel circuit Pc in this example include: a first TFT 30A; and a second TFT 30B.

The first TFT 30A has: a gate electrode 36 connected to the corresponding gate line 26g; the first terminal electrode 40 connected to the corresponding source line 26s; and the second terminal electrode 42 connected to the second TFT 30B. The second TFT 30B has: a gate electrode 36 connected to the second terminal electrode 42 of the first TFT 30A; the first terminal electrode 40 connected to the corresponding power supply line 26p; and the second terminal electrode 42 connected to a pixel electrode of the organic EL element 62. The capacitor 50 has: the first capacitive electrode 52 connected to the power supply line 26p; and the second capacitive electrode 54 connected to the second terminal electrode 42 of the first TFT 30A.

### Sealing Film

The sealing film 80 is provided in an upper portion of the light-emitting-element layer 60. The sealing film 80 covers the plurality of organic EL elements 62, and protects each of the organic EL elements 62 (in particular, the organic EL layers 66) from, for example, water and oxygen. The sealing film 80 has, for example, a thin-film encapsulation (TFE) structure. The sealing film 80 includes an inorganic layer, an organic layer, and an inorganic layer stacked on top of an other in the stated order. The inorganic layers are made of an inorganic insulating material such as silicon nitride. The organic layer is made of an organic resin material such as epoxy resin.

### Touch Panel

The touch panel TP is provided on the display panel DP. The touch panel TP is an on-cell touch panel. The touch panel TP is a projected capacitive touch panel. The touch panel TP includes: a plurality of first detecting electrodes 100; a plurality of second detecting electrodes 110; a plurality of touch panel lines 130; an interlayer insulating film 140; and an overcoat film 150.

The plurality of first detecting electrodes 100 are arranged in a matrix in the touch region TA. The plurality of second detecting electrodes 110 are also arranged in a matrix in the touch region TA. The first detecting electrodes 100 and the second detecting electrodes 110 are electrodes for detecting touch positions. The first detecting electrodes 100 and the second detecting electrodes 110 are alternately arranged in oblique directions with respect to the first direction X and the second direction Y.

Each of the first detecting electrodes 100 is shaped into, for example, a rhombus. The first detecting electrodes 100 arranged side by side in the first direction X have corners facing each other. The first detecting electrodes 100 arranged side by side in the second direction Y also have corners facing each other. The corners of the first detecting electrodes 100 arranged side by side in the first direction X are connected together through a first connecting line 102. The plurality of first detecting electrodes 100 arranged in the first direction X constitute a first electrode group 104.

Each of the second detecting electrodes 110 is shaped into, for example, a rhombus. The second detecting electrodes 110 arranged side by side in the first direction X have corners facing each other. The second detecting electrodes 110 arranged side by side in the second direction Y also have corners facing each other. The corners of the second detecting electrodes 110 arranged side by side in the second direction Y are connected together through a second connecting line 112. The plurality of second detecting electrodes 110 arranged in the second direction Y constitute a second electrode group 114.

The plurality of touch panel lines 130 are provided to the picture-frame region FA. In the touch panel TP, each of the touch panel lines 130 is lead from the touch region TA, and extends to the second terminal unit T2. The touch panel lines 130 are wires included in the touch panel TP. The touch panel lines 130 have respective end portions positioned in the second terminal unit T2 and serving as terminals 130t. The second terminal unit T2 is provided with the plurality of terminals 130t. The touch panel lines 130 include: a plurality of first touch panel lines 130a; and a plurality of second touch panel lines 130b.

Each of the plurality of first touch panel lines 130a is connected to one of a plurality of the first electrode groups 104. Each of the first touch panel lines 130a is routed to the second terminal unit T2, through a portion forming one side (the left side in the example illustrated in FIG. 4) of the picture-frame region FA in the first direction X. Some of the first touch panel lines 130a may be routed to the second terminal unit T2, through a portion forming an other side (the right side in FIG. 4) of the picture-frame region FA in the first direction X.

In the picture-frame region FA, the plurality of first touch panel lines 130a are spaced apart from, and laid in parallel with, one another, and provided to cross the folding portion B. Each of the plurality of second touch panel lines 130b is connected to one of a plurality of the second electrode groups 114. Each of the second touch panel lines 130b is lead to the second terminal unit T2 from a portion forming a side of the picture-frame region FA toward the terminal unit T. In the picture-frame region FA, the plurality of second touch panel lines 130b are also spaced apart from, and laid in parallel with, one another, and provided to cross the folding portion B.

To each of the terminals 130t of the second terminal unit T2, a touch detecting circuit (not shown) is connected through the wiring board CB. Each terminal 130t and the wiring board CB are connected together, using a current-carrying conductive junction material such as an anisotropic conductive film (ACF). When the touch region TA is touched with a contact object, the touch detecting circuit detects a variation in capacitance generated between an electrode included in the touch panel TP and the contact object.

The plurality of first detecting electrodes 100, a plurality of the first connecting lines 102, and the plurality of first touch panel lines 130a are provided on the sealing film 80. The plurality of first detecting electrodes 100, the plurality of the first connecting lines 102, and the plurality of first touch panel lines 130a are formed of the same material and in the same layer. The interlayer insulating film 140 is provided to cover the plurality of first detecting electrodes 100, the plurality of the first connecting lines 102, and the plurality of first touch panel lines 130a.

The interlayer insulating film 140 is made of the same inorganic insulating material as that of the first interlayer insulating film 38a of the TFT layer 20. The interlayer insulating film 140 is either a monolayer film or a multilayer film made of the inorganic insulating material. The plurality of second detecting electrodes 110, a plurality of the second connecting lines 112, and the plurality of second touch panel lines 130b are provided on the interlayer insulating film 140. The plurality of second detecting electrodes 110, the plurality of the second connecting lines 112, and the plurality of second touch panel lines 130b are formed of the same material and in the same layer.

The plurality of first detecting electrodes 100, the plurality of first connecting lines 102, the plurality of first touch panel lines 130a, the plurality of second detecting electrodes 110, the plurality of second connecting lines 112, and the plurality of second touch panel lines 130b are made of a conductive oxide transparent to light. Examples of the conductive oxide include indium tin oxide (ITO) and indium zinc oxide (IZO). These electrodes and wires are either monolayer films or multilayer films made of such conductive oxides.

The overcoat film 150 is provided in the touch region TA to cover the plurality of second detecting electrodes 110 and the plurality of second connecting lines 112. The overcoat film 150 is provided to cover each of the touch panel lines 130 in the picture-frame region FA except the second terminal unit T2 (e.g., to cover the first touch panel lines 130a through the interlayer insulating film 140 and to cover the second touch panel lines 130b directly). The overcoat film 150 is made of, for example, a light-transparent resin material such as acrylic resin.

### Polarizing Plate

The polarizing plate PP is provided above the touch panel TP. The polarizing plate PP is an example of a plate body. The polarizing plate PP is, for example, a circular polarizing plate, and prevents an interior of the panel from reflecting light. The polarizing plate PP is attached through a first adhesive layer 160 to a portion, of the display panel DP, including the display region DA. Examples of the first adhesive layer 160 include an acrylic adhesive. The polarizing plate PP, corresponding to the display region DA as a whole, is disposed over the display region DA to the picture-frame region FA.

### Cover Panel

The cover panel CP is provided above the polarizing plate PP. The cover panel CP protects a surface of the organic EL display device 1. The cover panel CP is, for example, a glass panel. The cover panel CP may be made of a transparent resin material such as polycarbonate. The cover panel CP is attached to the polarizing plate PP through a third adhesive layer 170. Examples of the third adhesive layer 170 include an optically clear double-sided adhesive film (OCA). The cover panel CP, corresponding to the display region DA as a whole, is disposed over the display region DA to the picture-frame region FA.

### Back Face Protective Film

The back face protective film PF is stacked across the display panel DP from the polarizing plate PP. The back face protective film PF blocks, for example, moisture and oxygen entering from the back face of the organic EL display device 1. The back face protective film PF is an example of a flexible sheet. The back face protective film PF of this example is made of a laminate film. The back face protective film PF is adhered to a back face of the substrate layer 10. The back face protective film PF is attached through a second adhesive layer 180 to a portion, of the display panel DP, including the display region DA. The second adhesive layer 180 of this example is a laminate glue.

### Structure of Folding Portion

The folding portion B has a folding groove GL formed in a multilayer film made of the base coat film 22, the gate insulating film 34, and the interlayer insulating film of the TFT layer 20. The folding groove GL penetrates the TFT layer 20 (the multilayer film) and exposes the substrate layer 10. The folding groove GL penetrates in a direction in which the folding portion B extends. In the folding groove GL, a filler layer FL is provided. The folding groove GL does not have to penetrate the TFT layer 20.

The filler layer FL fills the folding groove GL. The filler layer FL is formed of a resin material such as polyimide resin, acrylic resin, or polysiloxane resin. The upper lead lines 26hu included in the plurality of lead lines 26h extend on the filler layer FL, to cross the folding portion B in the second direction Y The plurality of upper lead lines 26hu are covered with an insulating film. The insulating film is, for example, a portion of the planarization film 56.

The plurality of first touch panel lines 130a extend on the insulating film (the planarization film 56) covering the lead lines 26h, to cross the folding portion B in the second direction Y The plurality of first touch panel lines 130a are covered with the interlayer insulating film 140. The plurality of second touch panel lines 130b extend on the interlayer insulating film 140, to cross the folding portion B in the second direction Y.

In the folding portion B, the polarizing plate PP is not provided. In the polarizing plate PP, an opening 190 is formed. The opening 190 extends linearly from one end to an other end of the polarizing plate PP in the first direction X along the folding portion B. The opening 190 is formed to have widths, in both the first direction X and the second direction Y, corresponding to the folding portion B as a whole. The polarizing plate PP is divided at the folding portion B by the opening 190.

Then, the folding portion B is provided with the first adhesive layer 160. The first adhesive layer 160 expands over an entire region between the two divided polarizing plates PP. The first adhesive layer 160 extends monolithically to a portion, toward the display region DA, corresponding to the polarizing plate PP, the folding portion B, and a portion, toward the terminal unit T, corresponding to the polarizing plate PP. The first adhesive layer 160 is provided to cover: the first touch panel lines 130a through the interlayer insulating film 140 and the overcoat film 150; and the second touch panel lines 130b through the overcoat film 150.

Furthermore, in the folding portion B, the back face protective film PF is not provided. In the back face protective film PF, an opening 195 is provided. The opening 195 extends linearly from one end to an other end of the polarizing plate PP in the first direction X along the folding portion B. The opening 195 is formed to have widths, in both the first direction X and the second direction Y, corresponding to the folding portion B as a whole. The back face protective film PF is divided at the folding portion B by the opening 195.

Then, the folding portion B is provided with the second adhesive layer 180. The second adhesive layer 180 expands over an entire region between the two divided back face protective film PF. The second adhesive layer 180 extends monolithically to a portion, toward the display region DA, corresponding to the back face protective film PF, the folding portion B, and a portion, toward the terminal unit T, corresponding to the back face protective film PF. The second adhesive layer 180 faces the filler layer FL across the substrate layer 10 at the folding portion B.

### Operation of Organic EL Display Device

In the organic EL display device 1, the plurality of gate lines 26g are sequentially selected and brought active. In each of the subpixels Sp, when the corresponding gate line 26g is brought active, a gate signal is input into the first TFT 30A through the gate line 26g, and the first TFT 30A turns ON. When the first TFT 30A turns ON, a voltage, corresponding to a source signal to be transmitted through the source line 26s, is applied to the gate electrode 36 of the second TFT 30B. Simultaneously, the voltage is written to the capacitor 50.

Then, when the second TFT 30B turns ON, a drive current, corresponding to a gate voltage of the second TFT 30B, is supplied from the power supply line 26p through the second TFT 30B to the organic EL element 62. Hence, in each subpixel Sp, the organic EL layer 66 (the light-emitting layer) emits light. As a result, an image is displayed. Note that, even if the first TFT 30A turns OFF, the gate voltage of the second TFT 30B is held in the capacitor 50. Hence, each subpixel Sp allows the organic EL layer 66 to keep emitting light until a gate signal in a succeeding frame is input.

### Method for Manufacturing Organic EL Display Device

A method for manufacturing the organic EL display device 1 includes a panel producing step, a plate body attaching step, and a plate body removing step.

### Panel Producing Step

The panel producing step involves producing the panel body PL including the display panel DP and the touch panel TP. Specifically, first, a resin material is applied to a surface of a glass substrate and baked. Thus, the substrate layer 10 is formed. Next, on the substrate layer 10, the display panel (the TFT layer 20, the light-emitting element layer 60, and the sealing film 80), and the touch panel TP are formed in the stated order, using a known technique such as photolithography, vacuum evaporation, spin coating, or inkjet printing.

### Plate Body Attaching Step

The plate body attaching step involves attaching the polarizing plate PP to the panel body PL. Specifically, first, the polarizing plate PP is prepared to have the back face provided with an adhesive. Alternatively, the adhesive is applied to the back face of the polarizing plate PP. Next, the surface, of the polarizing plate PP, provided with the adhesive is overlaid on the surface of the panel body PL, and the adhesive is cured. Hence, the first adhesive layer 160 is formed. In this way, the polarizing plate PP is attached through the first adhesive layer 160 over the display region DA and the folding portion B of the panel body PL, and further the region closer to the terminal unit T than the folding portion B.

### Plate Body Removing Step

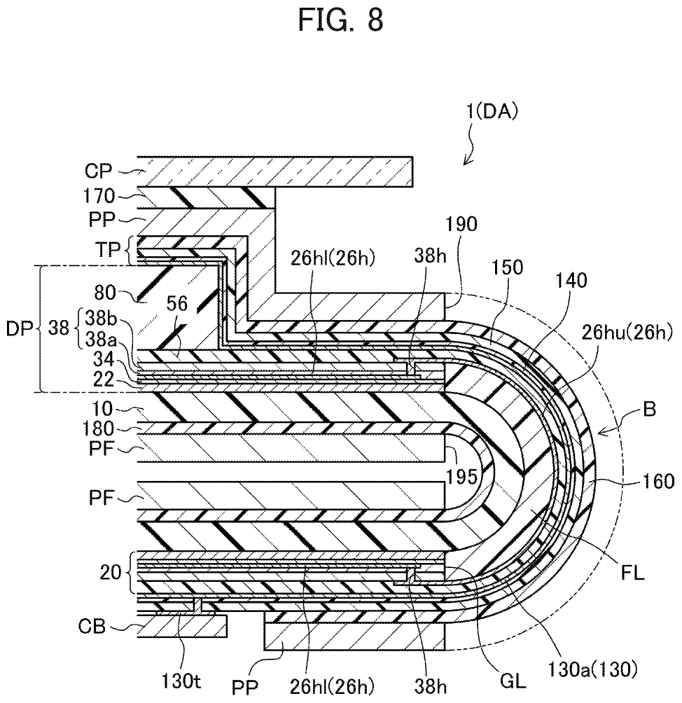

The plate body removing step involves partially removing the polarizing plate PP attached to the panel body PL. Specifically, a laser beam is emitted to, and removes, a portion included in the polarizing plate PP and positioned in the folding portion B (the removed portion is illustrated by a dash-dot-dot-dash line in FIG. 8). Here, in the folding portion B, the polarizing plate PP is completely cut. However, the first adhesive layer 160 is left uncut and exposed from the polarizing plate PP. The polarizing plate PP can be removed not only with a laser beam but also with any given cutting means such as a wheel cutter.

Then, a laser beam is emitted from toward the glass substrate to a back face of the substrate layer 10. Thus, the glass substrate is removed from the substrate layer 10. Subsequently, the back face protective film PF is attached to the back face of the substrate layer 10. Then, a laser beam is emitted to, and removes, a portion included in the back face protective film PF and positioned in the folding portion B. Thus, the wiring board CB is connected to each of the first terminal unit T1 and the second terminal unit T2 of the panel body PL. Hence, together with the wiring board CB, the source driver and the touch detecting circuit are mounted.

As described above, the organic EL display device 1 is successfully manufactured.

### Features of Embodiment

In the organic EL display device 1 of this embodiment, the polarizing plate PP is attached through the first adhesive layer 160 to a portion, of the display panel DP, including the display region DA. This polarizing plate PP is not provided to the folding portion B. Such a feature can reduce bending stiffness of the folding portion B. Then, in the folding portion B, the first adhesive layer 160 is provided to cover the touch panel lines 130. Hence, the first adhesive layer 160 can function as a protective layer. Such a feature can appropriately protect the touch panel lines 130 extending in the folding portion B in the picture-frame region FA of the organic EL display device 1.

In the organic EL display device 1 of this embodiment, the back face protective film PF is attached through the second adhesive layer 180 to a portion, of the display panel DP, including the display region DA. This back face protective film PF is not provided to the folding portion B. Such a feature is advantageous to reduce bending stiffness of the folding portion B. Then, the folding portion B is provided with the second adhesive layer 180. Hence, the second adhesive layer 180 can function as a protective layer. Such a feature can reinforce stiffness of the folding portion B and protect the wires extending in the folding portion B.

In the method for manufacturing the organic EL display device 1 of this embodiment, the polarizing plate PP is attached through the first adhesive layer 160 to the panel body PL over the display region DA and the folding portion B. Then, a portion, which is included in polarizing plate PP attached to the panel body PL and is positioned in the folding portion B, is removed so that the first adhesive layer 160 is exposed from the polarizing plate PP in the folding portion B. As a result, the bending stiffness of the folding portion B can be reduced, and the first adhesive layer 160 can function as a protective layer. Such a feature is suitable for manufacturing the organic EL display device 1 of this example.

### First Modification

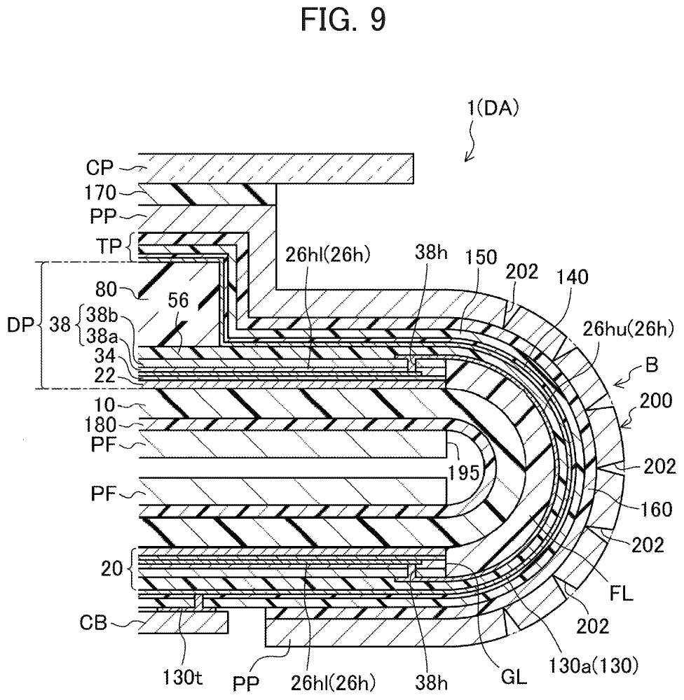

As illustrated in FIG. 9, in the organic EL display device 1 of this first modification, the polarizing plate PP has a flexible portion 200. In the flexible portion 200, a portion around a folding axis Ab is more flexible than an other portion. The flexible portion 200 is provided to the folding portion B. The folding portion B is provided with the first adhesive layer 160 together with the flexible portion 200 of the polarizing plate PP, so as to cover: the first touch panel lines 130a through the interlayer insulating film 140 and the overcoat film 150; and the second touch panel lines 130b through the overcoat film 150.

The flexible portion 200 of the polarizing plate PP is provided with a plurality of slits 202. The plurality of slits 202, each extending in the first direction X, are spaced apart from one another in the second direction Y Each of the slits 202 penetrates through the polarizing plate PP (the flexible portion 200), and extends in a direction in which the folding portion B extends. An outward opening away from the folding axis Ab of each slit 202 opens wider as the folding portion is folded. Thanks to the slits 202, the flexible portion 200 of the polarizing plate PP becomes more flexible.

### Method for Manufacturing Organic EL Display Device

A method for manufacturing the organic EL display device 1 includes a panel producing step, a plate body attaching step, and a plate body processing step. The panel manufacturing step and the plate attaching step are the same as those of the above embodiment.

### Plate Body Processing Step

The plate body processing step involves processing a portion of the polarizing plate PP attached to the panel body PL, so that the portion enhances flexibility around the folding axis Ab. In this example, the processing applied to the polarizing plate PP is slit processing. Specifically, a laser beam is emitted to a portion included in the polarizing plate PP and positioned in the folding portion B to form the plurality of slits 202 (the cut portions are illustrated by a dash-dot-dot-dash line in FIG. 9). Here, in the folding portion B, the polarizing plate PP is completely cut. However, the first adhesive layer 160 is left uncut. The slits 202 can be formed in the polarizing plate PP not only with a laser beam but also with any given cutting means such as a wheel cutter.

After that, as seen in the above embodiment, the glass substrate is removed from the substrate layer 10, and the back face protective film PF is attached to the back face of the substrate layer 10. After that, for example, a portion included in the back face protective film PF and positioned in the folding portion B is removed. Hence, the organic EL display device 1 is successfully manufactured.

### Features of First Modification

In the organic EL display device 1 of this first modification, the polarizing plate PP has the flexible portion 200. Then, in the folding portion B, the first adhesive layer 160 is provided together with the flexible portion 200 of the polarizing plate PP to cover the touch panel lines 130. As a result, the bending stiffness of the folding portion B can be reduced, and the first adhesive layer 160 can function as a protective layer. Furthermore, the flexible portion 200 of the polarizing plate PP is provided to the folding portion B, thereby increasing strength of the folding portion B.

In the organic EL display device 1 of this first modification, the flexible portion 200 of the polarizing plate PP is provided with the plurality of slits 202 extending in the first direction X and spaced apart from one another in the second direction Y Thanks to such a feature, the polarizing plate PP is suitably provided with the flexible portion 200, and the flexible portion 200 is readily provided in the folding portion B.

As to the organic EL display device 1 of this first modification, the slit processing is carried out to form the plurality of slits 202 in a portion that is included in the polarizing plate PP attached to the panel body PL and is positioned in the folding portion B. Hence, the portion enhances flexibility around the folding axis Ab. As a result, when the polarizing plate PP is provided with the flexible portion 200, the bending stiffness of the folding portion B can be reduced, and the first adhesive layer 160 can function as a protective layer. Such a feature is suitable for manufacturing the organic EL display device 1 of this example.

### Second Modification

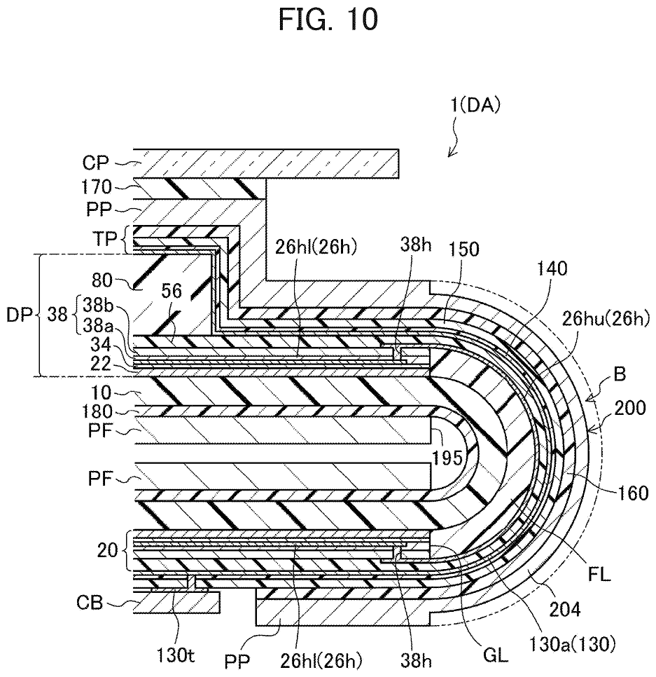

As illustrated in FIG. 10, in the organic EL display device 1 of this second modification, the polarizing plate PP has the flexible portion 200 as seen in the first modification. The flexible portion 200 has a thin portion 204 thinner than an other portion of the polarizing plate PR For example, the thin portion 204 is approximately 20% to 50% as thick as the other portion of the polarizing plate PR The thin portion 204 is provided over the folding portion B as a whole. The thin portion 204 is formed to have a substantially constant thickness.

### Method for Manufacturing Organic EL Display Device

A method for manufacturing the organic EL display device 1 includes a panel producing step, a plate body attaching step, and a plate body processing step. The panel manufacturing step and the plate attaching step are the same as those of the above embodiment.

### Plate Body Processing Step

The plate body processing step involves processing a portion of the polarizing plate PP attached to the panel body PL, so that the portion enhances flexibility around the folding axis Ab. In this example, the processing applied to the polarizing plate PP is thinning processing. Specifically, a laser beam is emitted to a portion included in the polarizing plate PP and positioned in the folding portion B to partially remove a surface of the polarizing plate PP (the removed portion is illustrated by a dash-dot-dot-dash line in FIG. 10). The polarizing plate PP can be partially removed not only with a laser beam but also with an other cutting means.

After that, as seen in the above embodiment, the glass substrate is removed from the substrate layer 10, and the back face protective film PF is attached to the back face of the substrate layer 10. After that, for example, a portion included in the back face protective film PF and positioned in the folding portion B is removed. Hence, the organic EL display device 1 is successfully manufactured.

### Features of Second Modification

In the organic EL display device 2 of this second modification, the polarizing plate PP has the flexible portion 200. Then, in the folding portion B, the first adhesive layer 160 is provided together with the flexible portion 200 of the polarizing plate PP to cover the touch panel lines 130. As a result, the bending stiffness of the folding portion B can be reduced, and the first adhesive layer 160 can function as a protective layer. Furthermore, the flexible portion 200 of the polarizing plate PP is provided to the folding portion B, thereby increasing strength of the folding portion B.

In the organic EL display device 1 of this second modification, the flexible portion 200 of the polarizing plate PP has the thin portion 204. Thanks to such a feature, the polarizing plate PP is suitably provided with the flexible portion 200, and the flexible portion 200 is readily provided in the folding portion B.

In the organic EL display device 1 of this second modification, the thin portion 204 of the polarizing plate PP is provided over the folding portion B as a whole. Such a feature can appropriately reduce bending stiffness of the folding portion B, while the portion included in the polarizing plate PP and provided in the folding portion B entirely serves as the flexible portion 200.

As to the organic EL display device 1 of this second modification, the thinning processing is carried out to partially thin the polarizing plate PP, so that the thinned portion, which is included in the polarizing plate PP attached to the panel body PL and is positioned in the folding portion B, enhances flexibility around the folding axis Ab. As a result, when the polarizing plate PP is provided with the flexible portion 200, the bending stiffness of the folding portion B can be reduced, and the first adhesive layer 160 can function as a protective layer. Such a feature is suitable for manufacturing the organic EL display device 1 of this example.

### OTHER EMBODIMENTS

In the above embodiment, the organic EL display device 1 includes the polarizing plate PP serving as a plate body. However, the organic EL display device 1 shall not be limited to such a case. The polarizing plate PP is solely an example of the plate body. Any given constituent member can be employed as the plate body as long as the plate body is shaped into a plate and attached through the first adhesive layer 160 to a portion including the display region DA of the display device.

In the above embodiment, the back face protective film PF is stacked across the display panel DP from the polarizing plate PP. However, the back face protective film PF shall not be limited to such a case. Instead of the back face protective film PF, an other flexible film or sheet may be stacked across the display panel DP from the polarizing plate PP, so as to serve as a flexible sheet.

In the above embodiment, the organic EL layer 66 is individually provided for, but not limited to, each subpixel Sp. The organic EL layer 66 may be provided monolithically in common to a plurality of subpixels Sp. In this case, the organic EL display device 1 may include, for example, a color filter so that each of the subpixels Sp presents a color tone.

In the above embodiment, each pixel Px includes subpixels Sp presenting, but not limited to, three colors. The colors of the subpixels Sp included in each pixel Px are not limited to three colors. The colors may be four or more colors. Furthermore, the subpixels Sp included in each pixel Px and presenting three colors are arranged in, but not limited to, stripes. The plurality of subpixels Sp may be arranged in an other manner such as PenTile Matrix.

In the above embodiment, the plurality of TFTs 30 constituting the pixel circuit Pc include, but not limited to, two TFTs; namely, the first TFT 30A and the second TFT 30B. The plurality of TFTs 30 constituting the pixel circuit Pc may include three or more TFTs. Furthermore, in the above embodiment, the TFTs 30 are, but not limited to, top gate TFTs. The TFTs 30 may be bottom-gate TFTs.

In the above embodiment, the organic EL elements 62 are, but not limited to, top-emission organic EL elements. Each of the organic EL elements 62 may be a bottom-emission organic EL element in which light emitted from the organic EL layer 66 is released from toward the substrate layer 10. Furthermore, the organic EL element 62 may be a double-sided organic light-emitting element in which light emitted from the organic EL layer 66 is released from toward both the substrate layer 10 and the cover panel CP.

In the above embodiment, each pixel electrode 64 and the common electrode 68 are respectively, but not limited to, an anode and a cathode. The pixel electrode 64 may be a cathode, and the common electrode 68 may be an anode. In this case, the organic EL layer 66 has an inverted multilayer structure.

In the above embodiment, the organic EL layer 66 have, but not limited to, a five-layer structure including the hole injection layer, the hole transport layer, the light-emitting layer, the electron transport layer, and the electron injection layer. The organic EL layer 66 may have a three-layer structure including a hole injection and transport layer, the light-emitting layer, and an electron transport and injection layer. The organic EL layer 66 can have any given multilayer structure.

In the above embodiment, the example of the display device is, but not limited to, the organic EL display device 1 with a touch panel. A technique of the present disclosure is applicable to, for example, an organic EL display device without the touch panel TP and a display device including a plurality of light-emitting elements driven by a current. Examples of such a display device include a display device provided with quantum-dot light-emitting diodes (QLEDs); that is, light-emitting elements including layers containing quantum dots. In addition, the technique of the present disclosure is applicable to a liquid crystal display device and a plasma display device.

As can be seen, a preferred embodiment has been described as examples of the technique of the present disclosure. However, the technique of the present disclosure shall not be limited to the above examples. The technique is applicable to embodiments with appropriate modifications such as changes, substitutions, additions, and omissions of features. It will be understood by those skilled in the art that various modifications can be made to the above embodiment without departing from the spirit of the present disclosure, and that such modifications fall within the scope of the present disclosure.

### INDUSTRIAL APPLICABILITY

As described above, the technique of the present disclosure is useful for a display device and a method for manufacturing the display device.

### REFERENCE SIGNS LIST

Ab Folding Axis
B Folding Portion
DA Display Region
DP Display Panel
FA Picture-Frame Region
PF Back Face Protective Film
PL Panel Body
PP Polarizing Plate (Plate Body)
T Terminal Unit
TP Touch Panel
X First Direction
Y Second Direction
1 Organic EL Display Device (Display Device)
26h Lead Line (Wire)
26t Terminal
62 Organic EL Element (Light-Emitting Element)
130 Touch Panel Line (Wire)
130a First Touch Panel Line (Wire)
130b Second Touch Panel Line (Wire)
130t Terminal
160 First Adhesive Layer
180 Second Adhesive Layer
200 Flexible Portion
202 Slit
204 Thin Portion

1. A display device, comprising:
a display panel; and
a plate body stacked on the display panel,
wherein the display panel has: a display region configured to display an image; and a picture-frame region provided around the display region,
the picture-frame region includes: a terminal unit provided with a plurality of terminals; and a folding portion provided between the terminal unit and the display region,
the folding portion is folded about a folding axis extending in a first direction,
the picture-frame region is provided with a wire extending to cross the folding portion in a second direction perpendicular to the first direction,
the plate body is attached through a first adhesive layer to a portion, of the display panel, including the display region, and
the folding portion is provided not with the plate body but with the first adhesive layer to cover the wire.

2. A display device, comprising:
a display panel; and
a plate body stacked on the display panel,
wherein the display panel has: a display region configured to display an image; and a picture-frame region provided around the display region,
the picture-frame region includes: a terminal unit provided with a plurality of terminals; and a folding portion provided between the terminal unit and the display region,
the folding portion is folded about a folding axis extending in a first direction,
the picture-frame region is provided with a wire extending to cross the folding portion in a second direction perpendicular to the first direction,
the plate body is attached through a first adhesive layer to a portion, of the display panel,
including the display region, the plate body having a flexible portion in which a portion around the folding axis is more flexible than an other portion, and
the folding portion is provided with the first adhesive layer together with the flexible portion, so as to cover the wire.

3. The display device according to claim 2,
wherein the flexible portion is provided with a plurality of slits extending in the first direction and spaced apart from one another in the second direction.

4. The display device according to claim 2,
wherein the flexible portion has a thin portion thinner than the other portion of the plate body.

5. The display device according to claim 4,
wherein the thin portion is provided over the folding portion as a whole.

6. The display device according to claim 1, further comprising
a flexible sheet stacked across the display panel from the plate body,
wherein the flexible sheet is attached through a second adhesive layer to a portion, of the display panel, including the display region, and
the folding portion is provided not with the flexible sheet but with the second adhesive layer.

7. The display device according to claim 1,
wherein the plate body is a polarizing plate.

8. The display device according to claim 1, further comprising
an on-cell touch panel provided on the display panel,
wherein the wire is a touch panel line included in the on-cell touch panel.

9. The display device according to claim 1,
wherein the display panel includes an organic electroluminescence element serving as a light-emitting element to display an image.

10. A method for manufacturing the display device according to claim 1, the method comprising:
a plate body attaching step of attaching the plate body to a panel body, including the display panel, through the first adhesive layer over the display region and the folding portion; and
a plate body removing step of removing a portion: included in the plate body attached to the panel body; and positioned in the folding portion,
wherein, at the plate body removing step, the first adhesive layer is exposed from the plate body in the folding portion.

11. A method for manufacturing the display device according to claim 2, the method comprising:
a plate body attaching step of attaching the plate body to a panel body, including the display panel, through the first adhesive layer over the display region and the folding portion; and
a plate body processing step of processing a portion: included in the plate body attached to the panel body; and positioned in the folding portion, so that the portion enhances flexibility around the folding axis.

12. The display device according to claim 2, further comprising
a flexible sheet stacked across the display panel from the plate body,
wherein the flexible sheet is attached through a second adhesive layer to a portion, of the display panel, including the display region, and
the folding portion is provided not with the flexible sheet but with the second adhesive layer.

13. The display device according to claim 2,
wherein the plate body is a polarizing plate.

14. The display device according to claim 2, further comprising
an on-cell touch panel provided on the display panel,
wherein the wire is a touch panel line included in the on-cell touch panel.

15. The display device according to claim 2,
wherein the display panel includes an organic electroluminescence element serving as a light-emitting element to display an image.
